(19) United States
(12) Patent Application Publication
(10) Pub. No.: US 2009/0004093 A1
(43) Pub. Date: Jan. 1, 2009

(54) Materials and methods for the manufacture of large crystal diamonds

(76) Inventor: Han H. Nee, Newport Beach, CA (US)

Correspondence Address: Eternax Diamond, LLC, 564 Wald, Irvine, CA, 92618-4637, US

(21) Appl. No.: 12/231,127

(22) Filed: Aug. 29, 2008

Related U.S. Application Data
(63) Continuation-in-part of application No. 11/672,403, filed on Feb. 7, 2007.
(60) Provisional application No. 60/771,140, filed on Feb. 7, 2006.
(60) Provisional application No. 60/784,138, filed on Mar. 20, 2006.
(60) Provisional application No. 60/864,278, filed on Nov. 3, 2006.

(51) Int. Cl. C01B 31/06; C30B 25/00

(52) U.S. Cl. 423/446; 117/104

(57) ABSTRACT

Materials and Methods are provided for forming single crystal diamond growth using microwave plasma chemical vapor deposition (CVD) process in partial vacuum with a gaseous mixture containing a methane/hydrogen mixture with optional nitrogen, oxygen and xenon addition. The single crystal substrate can be ceramic material such as MgO, Al₂O₃, BaTiO₃, and the like. A surface of the single crystal substrate is coated using an electron beam evaporation device with an alloy of iridium and a component selected from the group consisting of iron, cobalt, nickel, molybdenum, rhenium and a combination thereof. The alloy coated single crystal substrate is positioned in a microwave plasma CVD reactor and upon being subjected to a biased enhanced nucleation treatment in the presence of a gaseous mixture of methane, hydrogen, and other optional gases with a biased voltage of negative 100 to 400 volts supports the growth of a large single crystal diamond on its coated surface.

### RELATED APPLICATIONS

This application is a continuation-in-part of Applicant's parent application Ser. No. 11/672,403, entitled MATERIALS AND METHODS FOR THE MANUFACTURE OF LARGE CRYSTAL DIAMONDS, filed Feb. 7, 2007. The parent application in turn claims the benefit of U.S. Provisional Application No. 60/771,140, filed Feb. 7, 2006 and U.S. Provisional Application No. 60/784,138 filed Mar. 20, 2006 and U.S. Provisional Application No. 60/864,278 filed Nov. 3, 2006. All of the above are hereby incorporated by reference.

### FIELD

This disclosure relates to substantially single crystal diamonds having a large cross-sectional area, substantially single crystal substrates for their growth and methods for their growth utilizing these new substrates.

### BACKGROUND

Diamond refers to the crystalline material composed of only carbon atoms (atomic number six in the periodic table). In the diamond lattice, one carbon atom forms four covalent bonds with its closest neighbors in a tetrahedral geometry. This simple structure has particularly unique physical properties. For example, diamond is the hardest material on earth and possesses the highest thermal conductivity of any known material. It also has the highest acoustic velocity of any solid and arguably has the widest optical transmission bandwidth of any solid materials, extending from the ultraviolet and far infrared into the microwave regions and beyond. For a transparent material, diamond has a very large refractive index leading to a large reflection coefficient and a small angle for total internal reflection which contribute directly to the “brilliance and fire” of well-polished diamonds used in jewelry. Electrically, diamond is an insulator, but can be doped with boron to make a p-type (with holes) semiconductor and doped with phosphorus or other materials to make a potentially n-type (with electrons) semiconductor. Sufficiently large and inexpensive diamonds could be used to make the p-n junction devices which form the basis of IC circuits, solar cells, light emitting diodes, and other electronic devices. Diamond has many unique and attractive properties, only its high cost, its size limitations and its scarcity prevent it from being used in a variety of electronic and related applications.

Until about 50 years ago, all the diamond materials on earth were made by “nature” in the earth's mantle. Although most of the diamonds occurring in nature are single crystals and occasionally substantially large crystals are found, a high quality rough diamond, of about 10 carats in weight, for gem purpose can easily cost 250,000 dollars or more. In the mid 1950's, the General Electric Company successfully made diamonds in the laboratory using a high temperature (1500° C. or higher) and high pressure technique (50,000 atmospheres or higher). This method is generally referred to as the high temperature, high pressure method (the “HTHP method”). Virtually all naturally-occurring diamonds and diamonds grown by the HTHP technique are single crystals. Following this initial success, a continuing effort has been underway to improve the process and to lower the cost of synthetic diamonds. As a result of these efforts the cost of a carat (0.2 gram weight) of diamond grit for grinding and polishing of other materials has fallen to within the range of a few dollars. However, the individual crystals in diamond grit are typically quite small, on the order of substantially less than 1 millimeter in size and 0.1 carat in weight. The ability to grow a low cost 25 carat single crystal diamond (a mere 5 grams) in the lab using the HTHP technique has remained a difficult and elusive goal. Accordingly, diamond has not yet become the material of choice for many practical engineering or scientific purposes it would otherwise be suited for.

In the past 20 to 30 years, a different diamond growth technique has developed: chemical vapor deposition (CVD). CVD can be carried out at relatively low temperatures (in the range of 1000° C. or less) and low pressures (in the range of 0.2 atmospheres or less). The technique, as it relates to the growth of diamonds, has gradually developed to use gases such as methane (CH₄) and hydrogen (H₂). Atomic hydrogen, a key aspect of this process, can be generated by a variety of excitation methods including microwaves, hot filaments, plasma torches, thermal torches, etc. Originally, it was thought that because the CVD process is carried out at low temperatures and pressures that it might provide diamonds more conveniently and at lower costs than the HTHP process. Unfortunately, years of government and private research in the US and abroad have not advanced the CVD technology for diamond growth adequately to provide sufficiently large and inexpensive diamonds for the elusive engineering and scientific applications. The CVD method of growing diamonds is hampered, in part by: 1) its slow diamond crystal growth rate (ranging from several microns per hour to a maximum of 50 to 100 microns per hour depending on diamond quality); 2) its quality limitations (i.e. a single crystal diamond can generally only be grown on a single crystal diamond substrate or a non-diamond single crystal substrate and substantially reflects the quality of that substrate); and 3) the size of the diamond grown is generally limited to the size of the substrate in at least two dimensions. The largest single crystal diamond substrates currently available commercially are in the range of about 5 mm×5 mm. These so-called ‘substrate diamonds’ are commonly grown using the HTHP technique. As a result, CVD diamonds grown on single crystal diamond substrates produced by the HTHP process similarly have a size limitation of from about 5 mm×5 mm. Generally the lateral growth of a single crystal diamond by a CVD process has proven limited and difficult.

U.S. Pat. No. 6,096,129 discloses a technique of growing single crystal diamonds on single crystal diamond substrates wherein the diamonds grown in successive iterations of the process are progressively larger. This is accomplished, in part, by successively growing diamonds having slightly larger lateral dimensions than the initial substrate. According to this method, each resulting diamond can be cut to form a new substrate which can then be used to grow a slightly larger diamond. Diamonds grown in this way are harvested and used as templates in successive rounds of diamond growth, producing slightly larger diamonds with each repetition. While it is possible to produce diamonds with larger size areas using this technique, the process is slow and inefficient; e.g. a large area single crystal diamond of high quality and having a diameter in the range of about 5 inches would be very difficult, if not impossible to make by using this technique.

Still another problem encountered using the CVD diamond growth process is a tendency to produce polycrystalline diamond structures. Unfortunately, polycrystalline diamonds do not have the same material properties as single crystal diamonds. Polycrystalline diamonds cannot be used as effectively as single crystal diamonds in many applications and in some application polycrystalline diamonds have virtually no utility. As a result, polycrystalline diamonds represents a less desirable material than single crystal diamonds.

Single crystal CVD diamonds grown from non-diamond substrates using CVD processes have been reported in the technical literature as being formed by a heteroepitaxial process. See, for example, Koji Kobashi, Diamond Films: Chemical Vapor Deposition for Oriented and Heteroepitaxial Growth, (London: Elsevier Science, 2005). Substantial technical literature exists concerning diamond growth by the CVD process. In addition to Kobashi, see also Jes Asmussen and D. K. Reinhard (Eds.), Diamond Films Handbook, (CRC Press, New York, 2002); D. K. Bowen and B. K Tanner, High Resolution X-ray Diffractometry and Topography (Taylor & Francis, London, 1998); and Siredey et al, “Dendritic Growth and Crystalline Quality of Nickel Based Single Grains,” J. Crystal Growth 130, 132-146 (1933). It is generally recognized that in order to grow a single crystal diamond having a large cross-sectional area that a large single crystal substrate is needed, preferably a non-diamond substrate.

As with single crystal diamonds produced from diamond substrates, the size of the single crystal diamond grown is limited by the size of the non-diamond substrate. The largest single crystal diamond grown on a non-diamond substrate was reportedly grown on an iridium single crystal deposited on the surface of a single crystal of MgO or SrTiO₃. This coated substrate was about 2 to 3 centimeters in diameter. Difficulties in making very large single crystals of MgO and SrTiO₃ has limited this approach in making larger single crystal diamonds.

It has long been recognized that the ability to grow large single crystal diamonds has immense technological and commercial significance. So far that challenge has been unmet. Various aspects disclosed herein address this problem.

The largest single crystal growth industry on earth is undoubtedly the silicon industry which reportedly grows about 10,000 to 20,000 tons of silicon single crystals every year. These silicon single crystals typically have a purity of 99.9999% or better and are used to make integrated circuits, microprocessors, DRAMs, flash memories, and the like. Single crystal silicon is grown using either the so-called Bridgman technique (U.S. Pat. No. 1,793,672) or the Czochraiski technique. The Bridgman technique typically uses a seed of single crystal silicon and a two zone furnace. One zone of the furnace is held at a high temperature while the other zone is held at lower temperature. A crucible of liquid silicon is gradually moved from the high temperature zone of the furnace to the lower temperature zone, thereby promoting the initiation of the solid single crystal growth from the seed crystal and its continuous growth within the melt.

In the Czochraiski technique, a crucible holding molten silicon is stationary and a seed single crystal of silicon is dipped into the melt and then pulled upward into a colder temperature zone and a single crystal solid is formed on the solid seed crystal due to the presence of a temperature gradient. The continuous pulling of the seed crystal upward promotes growth of the silicon in the direction of the seed. Both techniques have undergone continuous development over the past 50 years. It is now possible to grow single crystals of silicon from less than one inch in diameter to sizes of 12 inches or greater. Accordingly, large single crystal silicon substrates are readily accessible. However, single crystal silicon is poorly suited for use as a substrate for CVD diamond growth. This is because of the large lattice constant difference between diamond (0.357 nm) and silicon (0.548 nm). This discrepancy in lattice constants leads to a lattice misfit between silicon and diamond, and ultimately lattice imperfections in the resulting diamond. Other techniques for growing diamonds using silicon include growing an intermediate layer of silicon carbide (lattice constant 0.436 nm) between the silicon and the diamond (see U.S. Pat. Nos. 5,420,443, 5,479,875, and 5,562,769). These patents disclose reduced lattice misfit between SiC and the diamond, but report other problems such as diamond nucleation and difficulty separating the diamond from the substrate, which hampers the utility of this technique. Because of the substantial lattice misfit and the tendency of diamond surfaces to react with silicon at high CVD temperatures to form silicon carbide, silicon substrates show little promise as substrates for growing large single crystal diamonds. As a result, new approaches for growing larger diamond crystals having superior quality and properties are needed.

Other single crystal ceramic materials used for substrates include lead-magnesium niobate, lead titanate, and gadolinium gallium garnet. The Bridgman method (U.S. Pat. No. 6,899,761) and the Czochraiski technique (U.S. Pat. No. 4,534,821) have both been used to make a variety of ceramic substrates. But as a class of materials, ceramics substrates for growing diamonds are difficult to form because of the very high temperatures required, the difficulty in controlling stoichiometry, and the resulting lattice misfit between the diamond and the ceramic substrate. U.S. Pat. No. 6,383,288, discloses the use of barium titanate, alumina, and magnesium oxide as substrates for growing single crystal diamonds. However, these materials are inherently difficult to work with and have yet to provide a large single crystal diamond. Even if the difficulties in producing a single crystal ceramic substrate can be overcome, it is still not clear that based on current technology that a large high-quality single crystal diamond can be grown on such a substrate with a CVD process.

Another field where single crystal materials have been developed is in the area of superalloy materials. Superalloys find use, for example, as turbine blades and vanes for jet engines, and are commonly used to manufacture parts of the engine that are exposed to the highest operating temperatures. Directionally solidified and largely single crystal turbine blades made with nickel based superalloys have been developed and improved over about the last 35 years. For a further discussion of these materials and their uses, see U.S. Pat. Nos. 3,260,505, 3,519,063, 3,542,120, 3,532,155. Additionally, U.S. Pat. Nos. 3,536,121, 3,542,120, 3,494,709, 4,111,252, 4,190,094, and 4,548,255 relate to methods for producing largely single crystal nickel-based superalloys. Typical turbine blades have air-foil shaped cross-sections that are about 25 to 50 centimeters in length. A (100) crystal orientation is typically aligned with the longitudinal axis of the blade to maximize resistance to high temperature creep, stress rupture and thermal fatigue. The grain misorientation or deviation from the ideal (100) orientation in superalloys has been improving over the years from about +/−20 degrees (U.S. Pat. No. 3,494,709), +/−5 to 10 degrees (U.S. Pat. No. 4,548,255) to one degree or less (Siredey et al., 1993) as measured by either X-ray or Gamma-ray diffraction. A review of this technology can be found in the recent book entitled High Resolution X-ray Refractometry and Topography, cited above.

Single crystal superalloy growth can be accomplished by controlling the cooling rate of the melt from one end of the ingot to the other end. This is commonly done using a water-cooled copper plate and a properly oriented solid seed crystal that has the same composition as the superalloy. The method also uses a helical or spiral shaped selector, such that the multi-grain solidification front is restricted by the selector such that only one grain can grow out of the selector and continue to grow to the full length of the blade. In this manner certain large single crystal nickel based superalloy have been grown. The following composition is typical of a complex superalloy optimized for high temperature strength and based on nickel having a single crystal form: Co: 4%, Cr: 7.5%, Mo, 0.5%, W: 7.5%, Ta: 6%, Al: 5.5%, Ti: 0.9% and Hf: 0.1% by weight and further including a second phase volume fraction of Ni₃Al or Ti₃Al in the range of 60 to 70% in the heat treated state. This general technique has now been found to be suitable for growing large diameter single crystal substrates useful in growing single crystal diamonds by the CVD technique. Whether a single crystal having the complex composition of a superalloy can be used as a surface to grow diamond on is unknown at this time.

Recently, other substrate materials having a metal coating have been explored for growing large single crystal diamonds. Examples can be found in U.S. Pat. Nos. 5,743,957, 5,863,324 and 6,383,288. In these patents diamonds are grown on platinum coated MgO, Si, glass, CaF, alumina, barium titanate or strontium titanate and the like. However, the platinum surface did not form a good single crystal nor were the substrates beneath the platinum good single crystal substrates upon which to grow large high-quality single crystal diamonds. U.S. Pat. No. 6,080,378 discloses a method for growing a diamond on a surface or film of platinum, platinum alloy, iridium, iridium alloy, nickel, nickel alloy, silicon or metal silicides. The supporting substrate for these films are single crystals of LiF, MgO, calcium fluoride, nickel oxide, sapphire, strontium titanate, barium titanate, and the like. All of these substrate materials are very high melting point ceramics and are difficult to grow because of the exacting stoichiometry required to produce the single crystal substrate. It is difficult to make high-quality single crystals of these ceramics having a diameter in the range of from about 3 to about 5 inches.

U.S. Pat. Nos. 5,298,286, 5,449,531, 5,487,945 and 5,849,413, describe the deposition of single crystal diamonds on a non-diamond substrate such as nickel, cobalt, chromium, magnesium, iron and their alloys. However, neither the composition of the alloys used nor methods for their preparation in a large single crystal form are provided. The CVD methods disclosed in these patents require a substantial amount of carbon be dissolved in the substrate in order to suppress graphite growth and promote diamond growth. In these methods, heteroepitaxial growth conditions were difficult to maintain. As a result, only 85% of the nucleated grains of diamond were aligned in the same direction in a sample having only a 5 mm×5 mm area.

An overview of the art of preparing synthetic diamonds by the HTHP and CVD methods can be found in the following US patents and published applications: U.S. Pat. Nos. 4,997,636, 5,487,945, 5,404,835, 5,387,310, 5,743,957, 7,060,130, 7,128,794, 20060203346, and 2006266279. These references are hereby incorporated by reference for the purpose of illustrating the general level of skill in this art.

In view of the current state of the art, there is a need for new substrates suitable for growing large high quality single crystal diamonds, for new CVD methods for producing high quality large single crystal diamonds utilizing these new substrates, and for new larger size high quality single crystal diamonds for use in a variety of applications. Various aspects of this disclosure provide materials and methods to meet these needs.

### SUMMARY

One aspect of this disclosure involves a method for growing a single crystal diamond. The method involves selecting a single crystal substrate which includes a single crystal ceramic platform having at least one flat surface with a coating fixed on the flat surface of the platform; providing a mixture of gases comprising methane and hydrogen; and dissociating the methane and the hydrogen molecules in the presence of the substrate to cause deposition of a single diamond crystal onto the coating. The deposition of a single crystal diamond can be conveniently carried out using a Chemical Vapor Deposition process as described in more detail below. The diamond crystal deposited has the substantially the same crystal structure as the coated substrate. The coating is derived from an iridium alloy containing iridium and a component selected from the group consisting of iron, cobalt, nickel, molybdenum, rhenium and a combination of these metals. Embodiments of this method are capable of providing large high quality single crystal synthetic diamonds as well as polycrystalline diamonds.

As used herein, “ceramic” means a non-metallic, inorganic, crystalline material. Examples include MgO, Al₂O₃, and BaTiO₃. Persons having ordinary skill in the art may select any ceramic which will withstand processing conditions and which has a suitable lattice spacing, orientation, and structure.

Another aspect of the present disclosure is the large and high quality synthetic diamonds produced by the method described above. Preferred high quality synthetic diamonds produced by this method are substantially single crystal diamonds as evidenced by the diamonds having a (200) or any other major crystallographic plane such as (111) or (220) diffraction peak and a full-width half maximum (FWHM) of the diffraction peak of less than five degrees, as determined by a method selected from the group consisting of an X-ray rocking curve method and Gamma-ray rocking curve method. In reference 3, how to obtain the x-ray or Gamma ray rocking curve of a given crystallographic plane is explained. The more preferred high quality single crystal synthetic diamonds produced by this method will have a (200) or any other major crystallographic plane diffraction peak with a full-width half maximum (FWHM) of less than one degree, as determined by a method selected from the group consisting of an X-ray rocking curve method and Gamma-ray rocking curve method. Finally, the most preferred high quality synthetic diamonds produced by this method will have a (200) or any other major crystallographic plane diffraction peak and a full-width half maximum (FWHM) of the diffraction peak of less than 0.2 degree, as determined by a method selected from the group consisting of an X-ray rocking curve method and Gamma-ray rocking curve method.

Further aspects of this present disclosure involve embodiments of the method for preparing a layered substrate upon which single crystal diamonds can be grown. One embodiment of the method includes the steps of forming a substantially single crystal ceramic; transforming a portion of the single crystal into a platform having at least one flat surface; and coating the one flat surface with an iridium alloy which includes iridium and a metal selected from the group consisting of iron, nickel, cobalt, molybdenum, rhenium and a combination of the metals.

Single crystals suitable for forming a single crystal substrate or platform can be prepared by selecting an appropriate crystallization device having first and second crystallization chambers separated by a crystal orientation selector, adding a seed crystal to the crystallization chamber, introducing molten ceramic, and extracting heat from the molten ceramic to initiate crystallization within the first crystallization chamber and allowing crystallization to proceed through the crystal orientation selector into the second crystallization chamber. As crystallization proceeds into the second crystallization chamber, the crystal formed there is a single crystal having longitudinal and transverse dimensions, wherein the longitudinal dimension is substantially larger than its transverse dimension. Alternatively, single crystal ceramic or metal oxide substrate can be grown the Czochraiski method or the crystal pulling method for single crystal materials such as BaTiO₃, LiNbO₃, LiTaO₃, Al₂O₃ (sapphire), and so on.

Another aspect of the present disclosure involves the novel layered substrate or platform prepared by the method described above. Layered platforms useful for growing diamonds under CVD conditions include a substantially single crystal ceramic coated with a single crystal of an iridium alloy.

Preferred iridium alloys utilized in the coatings described in this disclosure typically contain from about 0.01 a/o % to about 36 a/o % rhenium, whereas more preferred alloys generally contain from about 0.01 a/o % to about 30 a/o % rhenium. Preferred iridium alloys can contain from about 0.01 a/o % to about 50 a/o % of the metal component. The preferred iridium or iridium alloy coatings are either single crystals or polycrystalline materials. The more preferred coatings are single crystal coatings.

Another aspect of the present disclosure includes a method for preparing a layered substrate suitable for growing a diamond crystal. The layered substrates can be prepared by selecting a suitable substrate or platform and coating the platform with an alloy of iridium and a component selected from the group consisting of iron, cobalt, nickel, molybdenum, rhenium and a combination thereof. Suitable substrates typically have at least one flat surface, and are derived from a single crystal ceramic substrate. During the coating step the platform can be heated to a preferred temperature ranging from about 500° C. to about 1400° C. or to a more preferred temperature range of from about 900° C. to about 1400° C. Preferred coating processes further include rotating the platform during the coating.

The single crystal substrates utilized as platforms according to this disclosure typically have longitudinal and transverse dimensions, and have a crystal structure oriented in a direction substantially parallel to the longitudinal dimension. A crystal structure, whether a substrate or a platform is substantially parallel to its longitudinal dimension if it is within 5° of its longitudinal dimension. Such single crystal articles are suitable upon being coated, as described below, for growing large single crystal diamonds (from about 2 to about 15 cm or larger) of high quality using microwave chemical vapor deposition. Upon completing a CVD deposition process utilizing the various coated substrates described in this disclosure, a coated substrate having a diamond film positioned on the coating surface can be obtained.

Consideration of appropriate single crystal articles and methods for their preparation are provided below. A layered single crystal platform can be prepared from a single crystal ingot, prepared in the manner described above, by removing the ingot from the crystallization device and cutting it into multiple discs or platforms, each about 2 to 3 mm in thickness and about 2 to 15 cm in diameter. After grinding and polishing the flat end surfaces, the discs are plasma treated, for example, in an atmosphere of hydrogen or oxygen to remove any imperfections on the surfaces due to grinding or polishing. The discs are then ready for the next processing step: thermally evaporating iridium alloyed with at least one of the following metals: iron, cobalt, nickel, molybdenum, rhenium or a combination of these metals, onto the surface of the disc. Various alloys that can be used include alloys that include about 0.01 a/o % to about 50 a/o % of other alloying elements in iridium-molybdenum alloy with Mo addition to Ir ranging from 0.01 a/o % to 16.0 a/o %, or iridium-rhenium alloy with rhenium addition to iridium from 0.01 a/o % to about 36.0 a/o %, or the same iridium-rhenium alloy with additional addition of iron, nickel or cobalt in the range of 0.01 a/o % to about 50.0 a/o % singly or in any combination. These materials may be deposited on the substrate by, for example, a “molecular beam epitaxy” technique which uses electron beams in a vacuum environment to evaporate the material. Afterwards, the Ir-alloy coated substrate is subjected to a heat treatment, under vacuum, at 600 to 1400° C. to promote single crystal (100) plane growth of the Ir-alloy coating.

One embodiment of the reaction involves placing the layered single crystal substrate into a microwave plasma CVD reactor and selecting conditions suitable for a biased enhanced nucleation (BEN) process. Such conditions can include, for example, operating at 1-2 kilowatts, 2.45 Giga Hertz frequency for a 5 cm diameter layered single crystal platform or up to 10 or 20 or higher kilowatts of microwave power at 915 Mega Hertz for a 15 cm diameter layered single crystal platform. Growth conditions include using methane/hydrogen gas in ratio of from about 0.1 to 100 to 10 to 100 at a pressure of from about 10 to about 300 torrs and a temperature of 500 to 1300° C. Further optional gaseous components include nitrogen, oxygen and xenon. Preferred levels of nitrogen generally range from about 5 ppm to about 5%, whereas more preferred levels of nitrogen generally range form about 30 ppm to about 2%. Preferred levels of oxygen generally range from about 0.01% to about 3%, while more preferred levels of oxygen range from about 0.1 to about 0.3%. Preferred levels of xenon typically range from about 0.1% to about 5%, and more preferably from about 0.1 to about 1.5%.

In one embodiment, the BEN process can be conducted in a gas concentration about 1-7% CH₄/H₂ ratio with about 20 to 500 ppm N₂ gas, at a substrate temperature 500 to 1000° C., a vacuum pressure of about 10 to about 50 Torrs, and substrate biased voltage of about negative 100 to about 400 volts with respect to the plasma for about 10 to about 60 minutes with about 0.15 to about 0.8 kilowatt of microwave power at about 2.45 Giga Hertz for an area of 1 cm diameter, and 1-2 kilowatt of microwave power for a disc of 5 cm diameter, the power of the microwave is proportional to the surface area of the sample. Further heteroepitaxial diamond growth can be achieved using high microwave power and higher substrate temperatures, lower methane/hydrogen gas ratios, increased vacuum pressures and increased nitrogen concentration. Oxygen in the range of about 0.1 to 0.3% of hydrogen and the rare gas xenon (Xe) gas in the range of 0.1 to 1.5% may also be added to increase the growth rate of diamond at this stage. The nucleation and growth of large single crystal diamond via the CVD process is accomplished by use of a large single crystal substrate with (100) orientation as provided by various embodiments described in this disclosure. Once the novel large high quality diamonds have been produced by the process described above, these diamonds can themselves be utilized as substrates and substituted for a layered substrate in embodiments of the CVD process described above. Additional similar high-quality diamonds can thus be produced with a layered substrate or a diamond produced from a layered substrate. By doping these new diamonds with boron and other materials during the CVD growth process, they can be made into p-type semiconductors and/or n-type semiconductors, respectively.

### BRIEF DESCRIPTION OF THE DRAWINGS

FIG. 1 is a cross sectional drawing of a single crystal substrate with an iridium alloy coating and a diamond single crystal coating on the alloy coating.

FIG. 1A is a cross sectional view of the article of FIG. 1, which in one embodiment is a single crystal substrate with an iridium alloy coating and a diamond single crystal coating on the alloy coating.

FIG. 2 is a schematic drawing of the modified directional solidification process mold for growing a single crystal ingot of ceramic.

FIG. 3 is a schematic drawing of the electron beam evaporation apparatus.

FIG. 4 is a schematic drawing of the microwave plasma CVD reactor for growing a single crystal diamond.

### DESCRIPTION

For the purposes of promoting an understanding of the principles of the invention, reference will now be made to the embodiments illustrated herein and specific language will be used to describe the same. It will nevertheless be understood that no limitation of the scope of the invention is thereby intended. Any alterations and further modifications in the described processes, systems or devices, and any further applications of the principles of the invention as described herein, are contemplated as would normally occur to one skilled in the art to which the invention relates. In addition, throughout this disclosure the term atomic percent has been abbreviated a/o %.

One aspect provides materials for CVD diamond growth comprising a substantially single crystal substrate having at least one surface coated with a material that promotes diamond growth in the CVD process. Further aspects of the disclosure include a method for producing a substantially single crystal substrate having at least one flat coated surface and a process for producing diamonds comprising the steps of providing the coated single crystal substrate described above and forming a substantially single crystal diamond on the coating's surface.

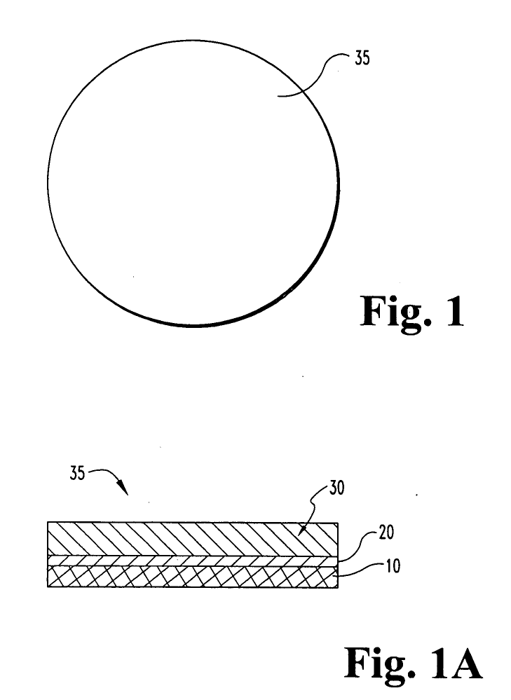

The ideal substrate on which to grow a single crystal diamond using the CVD process is a single crystal diamond. The size of the newly grown diamond is substantially limited to the size of the original diamond. Currently the largest commercial diamonds that could be used for such a substrate are probably no larger than about 5 mm×5 mm in two dimensions. Because of this limitation, synthetic diamonds made with a CVD process using a diamond substrate have a similar size limitation. FIG. 1 illustrates an embodiment of an article of manufacture 35 including non-diamond substrate suitable for growing a single crystal diamond in a CVD process in which the substrate can be made sufficiently large to overcome the size limitations that result from using diamond substrates and can produce a single crystal diamond over substantially an entire surface. With reference to FIG. 1A, which shows a cross-section of article 35 of FIG. 1, further embodiments include: a method of growing a substantially single crystal substrate 10 which comprises ceramic, the subsequent deposition of a coating 20 on at least one surface of substrate 10 wherein the coating 20 can include a single crystal of an iridium alloy, and a method for growing a synthetic diamond 30 in a single crystal form on a surface of coating 20. Different embodiments of these materials and methods are described below in greater detail.

### A Method for Forming a Substantially Single Crystal Substrate

The ability to efficiently grow large-size and high quality single crystal diamonds on the order of 2 to 15 centimeters or larger diameter using epitaxial techniques requires substrates for diamond growth that have essentially the same or similar crystal structure and lattice spacings as diamond. Various embodiments are based on a single crystal ceramic substrate. In one embodiment, a large size single crystal substrate having a diameter of from about 2 to about 15 centimeters or larger is formed using a modified directional solidification process described in detail below. Embodiments of this process include the steps of: providing a melt of a ceramic, adding a seed single crystal comprising the same material to the first crystallization chamber of a device having first and second crystallization chambers, a channel for the introduction of melt into the device and a crystal orientation selector positioned between the two chambers, introducing the melt to the device, and extracting heat from the melt to initiate solidification or crystallization within the first crystallization chamber. As heat is extracted from the melt in the region of the first crystallization chamber, crystallization initiates and proceeds toward and through the crystal orientation selector and into the second crystallization chamber. Upon completion a single crystal is formed within the second crystallization chamber having a longitudinal dimension which is substantially larger than its transverse dimension. Generally the single crystal formed is oriented substantially parallel to its longitudinal dimension.

Throughout the melting and pouring process the temperature gradient over the melt and the speed with which the solid-liquid interface moves through the melt during the solidification process are controlled to provide a grain misorientation of the final single crystal in the order of substantially less than 1 degree. The diameter of the single crystals formed by this process can be, for example, 2, 5, 15, 30 centimeters or even larger. The weight of the single crystal ingot may be on the order of 10 kg, 100 kg or larger.

In one embodiment the materials used to grow the single crystal substrate may be ceramic.

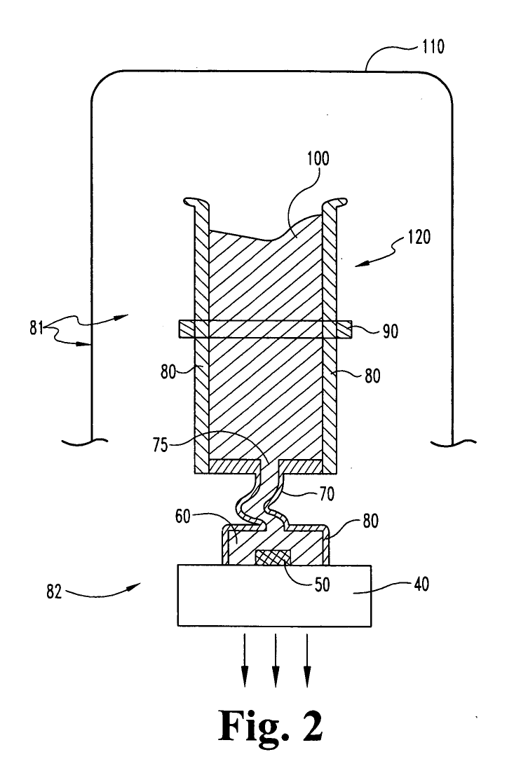

Referring now to FIG. 2, a vacuum casting furnace 110 may be used to melt the ceramic. Preferred melt conditions for the ceramic 100 include a vacuum and temperatures of about 150° C. to about 250° C. above the melting point of the ceramic. During the heating, melting and transferring steps, the ceramic and the resulting melt can be held in a graphite crucible. Next, the melt or molten material is transferred into a ceramic mold 80 with mechanical support 90 positioned to support the mold. The mold can be made of a mixture of alumina, and/or other high temperature refractory materials. In one embodiment a water-cooled copper cooling plate 40 is positioned at the bottom of the mold and a lower crystallization chamber. In this embodiment, a spiral or helical-shaped single crystal selector 70 is located between the upper crystallization chamber 81 and the lower crystallization chamber 82.

To operate the crystallization device an appropriate ceramic is melted to provide a molten mass 60 having a desired composition and a seed crystal 50 of the same material composition as the molten material and having a (100) orientation is placed in crystallization chamber 82. The molten mass is transferred into the mold and solidification begins in the cooler crystallization chamber 82 proximate cooling plate 40 in the presence of the seed crystal 50. Although preferred seed crystal 50 has the same general composition as the ceramic, some variation in the composition of the seed crystal is acceptable and can provide adequate single crystal substrates. This level of variability for the seed crystals is well within the ability of one skilled in this art to determine with minimal effort.

As the molten material cools it takes on the crystal orientation of the seed crystal. A temperature gradient is maintained across the mold to provide the lowest temperature in the crystallization chamber 82 and the higher temperature in crystallization chamber 81. Initially, the temperature in crystallization chamber 81 should be at least about 100° C. above the melting point of the material making up the melt. As the solidification front moves toward crystallization chamber 81, it moves into and through the crystal orientation selector 70 so that after the selector, at about location 75 only one crystal is growing into crystallization chamber 81.

This single crystal continues to grow into crystallization chamber 81 as the whole mold assembly 120 is physically lowered downward into a colder temperature zone away from the top of the furnace 110. Movement of assembly 120 is carried out in a manner that maintains a temperature gradient across the mold 80 that results in movement of the solidification interface across the gradient at a rate of from about 0.1 to about 10 inches per hour, and in certain embodiments at a rate of from about 0.2 to about 0.3 inches per hour.

With the molten ceramic described herein, this solidification process proceeds by dendritic growth in the (100) orientation. Although not required, this orientation is preferred because crystals of these materials having the (100) orientation generally grow faster than crystal forms having other orientations.

The temperature gradient in a mold arranged as illustrated in FIG. 2 aligns with the vertical direction and the cooling axis as in FIG. 2. The (100) direction of the crystal of the melt aligns first with the seed crystal, moves through the spiral or helical crystal orientation selector portion of the mold, allowing only one grain to continue growing into chamber 81. Crystallization is allowed to continue until at least a portion of crystallization chamber 81 is filled with crystalline material (100) having an orientation aligned vertically.

Using this technique, large single crystals of ceramic, including materials having the (100) orientation or cube on face type crystals, can be grown to provide a variety of cross-sectional dimensions. Preferred crystals have a cross-sectional dimension of at least about 1 inch, more preferred crystals have cross-sectional dimensions in the range of from about 2 inches to about 5 inches and other preferred crystals have cross-sectional dimensions up to from about 12 inches to about 20 inches or larger.

After growth of the single crystal is complete, the ingot can be annealed under vacuum at a temperature of from about 800 to about 1300° C. for several hours to further enhance the perfection of the crystal. Annealing the crystal is believed to reduce any residual misorientations in the single crystal and provide a crystal misorientation that is substantially less than one degree.

Preferred substrates processed in this manner typically provide substantially single crystals wherein the full-width half maximum (FWHM) of the (200) plane's x-ray or gamma ray rocking curve is less than about 5 degrees. More preferred substrates processed in this manner typically provide single crystals wherein the full-width half maximum (FWHM) of the (200) plane's x-ray or gamma ray rocking curve is less than about 1 degree. Still more preferred substrates processed in this manner typically provide single crystals wherein the full-width half maximum (FWHM) of the (200) plane's x-ray or gamma ray rocking curve is less than about 0.2 degrees. Platforms prepared from each of the single crystal substrates described above have full-width half maximums (FWHM) of the (200) plane diffraction peak corresponding to the same diffraction peak determined for the substrate from which the platform was prepared.

Single crystal rods or cylinders grown in this manner can be cut into preferred disc shaped substrates or platforms having at least one flat or generally planar surface and a thickness ranging from about 1 to 3 mm. The discs prepared in this manner can be further ground and polished mechanically, cleaned using a suitable cleaner and readied for the application of a coating of iridium alloy using, for example an electron beam evaporation process as described below.

The single crystal iridium alloy coatings or oriented films generally have full-width half maximums (FWHM) of the (200) plane diffraction peaks corresponding to the same diffraction peaks determined for the substrate supporting the iridium or iridium alloy coating or oriented film. Preferred coatings are substantially single crystals having an FWHM diffraction peak of less than about 5°, more preferred coatings can have an FWHM diffraction peak of less than about 1°, and the most preferred coatings can have an FWHM diffraction peak of less than about 0.20. The coated substrates disclosed herein are particularly useful for preparing large high quality diamonds in CVD process as will be described in more detail below.

### A Method for Coating a substantially Single Crystal Substrate with a Coating having a Lattice Crystal Orientation capable of Promoting the growth of substantially Single Crystal Diamond

The material used to form the coating for the single crystal substrate made in accordance with the methods provided above can be an iridium alloy. Examples of iridium alloys that can be used as coatings include Ir—Fe, Ir—Co, Ir—Ni or Ir—Re alloys.

Iridium alloys can be further alloyed with additional elements, in which these second alloying elements can be present at concentrations ranging from about 0.01 a/o % to about 50 a/o % of the coating alloy. Because the binary alloys of Ir—Ni, Ir—Co and Ir—Fe are all isomorphous alloy systems, Ir can be included in these alloys with any portion of Ni, Fe, or Co or mixture thereof to provide a homogeneous solid phase.

Examples of binary iridium alloys include combinations of the aforementioned alloys. Further examples of iridium alloys also include ternary alloys such as for example: Ir—Co—Fe, Ir—Co—Ni, Ir—Ni—Fe; or quaternary alloys such as Ir—Co—Fe—Ni. The total amount of each additional element alloyed with iridium can range from about 0.01 a/o % to about 50 a/o %.

In a further embodiment, the iridium is also combined with molybdenum, with the amount of molybdenum ranging from about 0.01 a/o % to about 20 a/o %. Other iridium alloys useful for coating the single crystal substrate include iridium-rhenium alloys. Preferred iridium-rhenium alloys contain from about 0.01 a/o % to about 36.0 a/o % of rhenium. In certain preferred embodiments the amount of rhenium in the alloys ranges between about 25.0 to about 35.0 a/o %.

In still further embodiments, the iridium alloys containing rhenium can be further alloyed with the additional elements, nickel, iron or cobalt or any combinations thereof, where the total additional elements range from about 0.01 a/o % to about 35.0 a/o % with regard to iridium. In one embodiment of the iridium/rhenium alloy, the concentration of rhenium in iridium is in the range of from about 25.0 a/o % to about 35.0 a/o % and the total concentration of nickel, iron and/or cobalt added to iridium is in the range of from about 20.0 a/o % to about 35.0 a/o %. In one embodiment, the amount of rhenium in the iridium alloy ranges from about 27.0 a/o % to about 33.0 a/o % and the amount of nickel and/or cobalt added to the iridium is ranges from about 15.0 a/o % to about 25.0 a/o %.

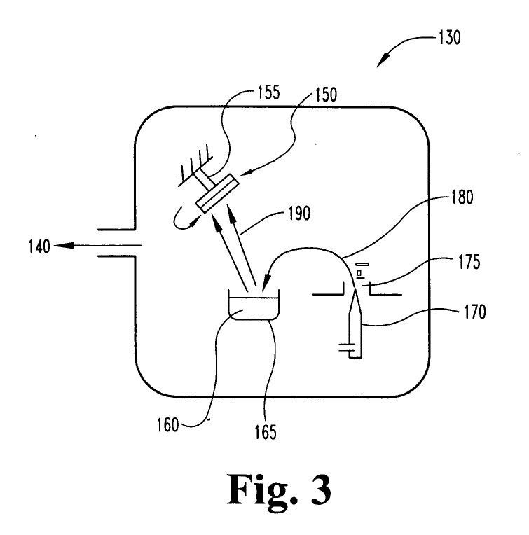

The various coating materials can include a variety of iridium alloys as described above. The iridium alloys can be made by vacuum arc melting of pure Ir and pure second or further alloying elements provided in the appropriate proportions. These coating materials, whether substantially pure iridium or master alloys, can then be placed in the evaporation hearth of a electron beam evaporation apparatus 130 as depicted in FIG. 3, wherein outlet 140 is connected to a vacuum pump, electrons 180 are generated by the electron gun 170, shaped by magnetic lens 175, and finally bent by a magnetic field to bombard coating material 160 held in a crucible 165. When enough energy is imparted to the coating material by impact of the electrons, the coating material will first melt and then evaporate to form a metallic vapor 190 that is directed toward the rotating substrate 150 which comprises a single crystal nickel or nickel-based alloy or other alloy substrate of the type described above.

Referring still to FIG. 3, a heating mechanism 155 is provided such that the single crystal substrate can be heated during the electron beam evaporation of the Ir alloy and its deposition onto substrate 150. It is preferable that the substrate be kept at a temperature ranging from between about 700 and about 1400° C., and rotated during the evaporation process to facilitate the formation of a single coating of a perfect or near perfect single crystal of Ir alloy on a surface of the single crystal substrate.

In one embodiment, the thickness of the coating on the substrate is in the range of about 200 to about 700 nm.

Regardless of the size of the single crystal substrate (i.e. 2 cm to 15 cm, for example), a coating of iridium alloy can be grown to cover the entire substrate's surface using this heteroepitaxial process.

Alternatively, the evaporation of an iridium alloy can be done by multiple-hearth electron beam evaporation process in which a plurality of electron beam guns is used. Each electron beam gun can be used to volatilize an iridium alloy or used to volatilize iridium and one or more single element(s) that make up the alloy composition, wherein each element can be held in a separate crucible or hearth. In this process, the evaporation rate of each element can be independently controlled by the heat input of each electron gun directed at each crucible or hearth. The composition of the material deposited on the single crystal substrate can be controlled by controlling the rate of evaporation of each element. Controlling the rate of metal evaporation can be facilitated with the use of evaporation flux monitoring devices.

In one embodiment, monitoring devices can provide information about the rate and/or amount of the evaporation of a single element or material. Feedback from these monitoring devices can be used to control the e-beam guns to ensure the correct stoichiometry of the coating is obtained. Alternatively, nickel, iron, cobalt or combinations thereof can be evaporated by using a high temperature effusion cell in a conventional thermal evaporation process operated simultaneously with electron beam guns evaporating, for example, Ir and Re from 2 separate crucibles.

A vacuum can be used to facilitate the evaporation of Ir, Re, Co, Fe or Ni. Typically, vacuums operated at pressures ranging from about 10⁻⁸ to 10⁻⁹ torr or deeper, will prove beneficial. The deposition rate onto the nickel or nickel alloy substrate is typically about one monolayer per second. This evaporation technique is commonly referred to as a “molecular beam epitaxy technique”.

Another aspect of this present disclosure involves a single crystal substrate having a coating which comprises a rhodium alloy prepared in the same manner as described above for the preparation of an iridium alloys. Single crystal substrates of the kind described above having a rhodium or rhodium alloy coating can also be used in a CVD process to grow large high quality diamonds. For example, rhodium can be alloyed with rhenium in amounts ranging from about 0.01 a/o percent to about 20 a/o percent rhenium or preferably in amounts ranging from about 5 to about 10 a/o percent rhenium in rhodium. Rhodium-rhenium alloys can be further alloyed with iron, nickel and/or cobalt individually or in combination ranging from about 0.01 a/o percent to about 40 a/o percent.

Producing at least one layer of diamond on the coated surface of a substantially single crystal substrate with a CVD process.

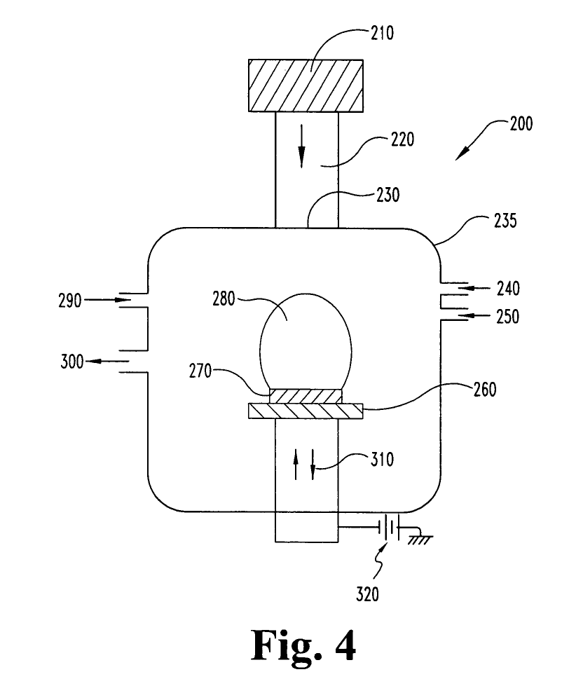

FIG. 4 illustrates a schematic diagram of a plasma CVD diamond reactor 200, having a microwave generator 210. A typical microwave generator operates at 2.45 GHz, 1-10 KW, or 915 MHz, 30 to 100 KW or 915 MHz, 200 or more KW depending on the substrate size. Microwaves move through a wave guide 220 passing through a quartz window 230 to generate a plasma ball 280 under a vacuum pressure from about 20 torrs to about 250 torrs.

The vacuum chamber 235 acts as the CVD reactor with several gas inlets which can include inlet 240 for methane, inlet 250 for hydrogen, inlet 290 for oxygen or nitrogen and other gas inlets (not shown) for any additional gases utilized. The reactor is evacuated using a vacuum pump 300 while various gases are fed into the chamber. A substrate 270 made, for example, according to the methods provided above, is located on top of a sample stage 260.

Cooling water 310 can be fed into the sample stage to remove heat from the substrate and maintain the temperature of the substrate at a desired level.

The sample stage is biased electrically by a circuit 320 with a potential difference in the range of about negative 100 to 400 volts. This helps promote nucleation of diamond crystals on the various alloy coatings described above.

The size of the plasma ball 280 can be controlled by the power input of the microwave generator 210, the flow rate of various gases introduced into the reactor and the vacuum pressure maintained within the reactor. At a specific vacuum level, the plasma ball will typically be smaller with higher gas flow rates.

The function of the microwave energy in the reactor is to decompose the molecular hydrogen gas into an atomic form of hydrogen. The atomic hydrogen can then react with methane to produce a source of carbon which is deposited on the substrate in the form of a diamond lattice structure.

The use of a biased enhanced nucleation process can facilitate the deposition of diamond onto a coating. Suitable coatings include single crystals of alloys of iridium, rhodium, or both.

A fairly typical diamond nucleation process uses a methane/hydrogen gas ratio of about 0.5 to about 10% or more preferably from about 3 to about 7%; a vacuum pressure of from about 10 to about 60 torrs; a substrate temperature of from about 700 to about 1300° C.; a biased voltage between the coated substrate on the sample stage and the counter electrode or the chamber wall of from about negative 100 to about 400 volts; and microwave power in the range of from about 0.5 to about 1 KW at 2.45 GHz to form diamonds on a sample area of 10 mm diameter. In one variation, the process uses microwave power of about 1-2 kW for a 50 mm diameter substrate. The amount of microwave power used is roughly proportional to surface area of the substrate.

The biased enhanced nucleation treatment time is often in the range of between about 10 to 60 minutes.

Once diamond is nucleated, a diamond coating on the coated alloy substrate is formed by changing the process parameters to about 1-3% methane/hydrogen ratio; no biased voltage applied on the sample stage; a vacuum pressure of about 100 to about 250 torrs; and a microwave power level of about 5 Kw or higher at about 2.45 Giga Hz for a 5 centimeter diameter substrate. The actual condition and settings can vary depending on the reactor used and the microwave power supply available.

Heteroepitaxial growth of diamond typically proceeds with the merging of various grains of diamond crystals of the same or similar orientation on the surface of the substrate to form a single grain of diamond. Oxygen, nitrogen and/or xenon can be added to the reactants to increase the rate of diamond growth. In general, a higher concentration relative of hydrogen gas to methane gas favors more perfect diamond crystal growth and suppresses graphite formation. The addition of nitrogen in the range of about 10 to about 500 ppm tends to stabilize the growth of (100) orientation crystals and to increase the rate of diamond growth. The addition of oxygen in the range of about 0.1 to about 0.3% of the total gas concentration also may increase the diamond growth rate. The addition of xenon gas in the range of about of 0.2 to about 2% similarly may increase the diamond growth rate.

Typical (100) oriented diamond growth rate may be in the range of about 5 to about 10 microns per hour or higher depending on the level of microwave power supplied to the process. Lattice misorientation in the diamond single crystal at 100 micron or higher thickness can be in the range of 5 degrees or less. It is more preferred that the lattice misorientation is about 1 degree or less. It is most preferred that the lattice misorientation is less than 0.2 degree.

Diamonds with these properties are similar to the lattice perfection found in natural diamonds. This lattice misorientation of diamond is measured by X-ray or Gamma-ray rocking curve of the (200) plane diffraction peak to have a FWHM of less than 5 degrees, with one degree of less more preferred and with 0.2 degree or less most preferred. It is further understood that if the initial ceramic substrate surface is a single crystal of (111) or (220) orientation, the iridium or rhodium alloys coating on the substrate will have a similar single crystal orientation of (111) or (220) after the molecular beam epitaxial growth process. Thus, a single crystal diamond of (111) or (220) orientation can be produced on top of the metal alloy coated substrate if a suitable microwave plasma chemical vapor deposition process with the proper BEN and growth process parameters as mentioned before are used.

In other words, the epitaxy relationship between the single crystal substrate, single crystal metal coating and the single crystal diamond can be: diamond's (111) plane parallels to Ir alloy coating's (111) plane parallels to ceramic substrate's (111) plane, and diamond (111) direction parallels to Ir alloy coating's (111) direction parallels to ceramic substrate's (111) direction; or diamond's (100) plane parallels to Ir alloy coating's (100) plane parallels to ceramic substrate's (100) plane, and diamond's (100) direction parallels to Ir alloy coating's (100) direction parallels to ceramic substrate's (100) direction.

### EXAMPLE 1

Ceramic can be used to grow a cylindrical shaped single crystal about 2.0 inches in diameter and about 5 inches long. This process can generally use a seed of (100) single crystal of ceramic.

After solidification, the top of the single crystal ingot can be cut and discarded. The remaining ingot can be heated in a vacuum furnace at about 1300° C. for about 5 hours, then “furnace cooled” to room temperature.

Next, a portion of the remaining ingot can be cut into discs about 2 mm thick with a diameter of about 2 inches. The disc can be then ground by 600 grit silicon carbide sanding paper with ample lubrication, successively polished with 3 microns diamond paste on a napless cloth, 0.5 micron diamond paste on a short-nap cloth and finally lapped with 0.1 micron diamond paste on a medium-nap cloth to a surface finish of better than 10 nanometers root-mean square surface roughness.

The single crystal misorientation of (100) plane as determined by rocking curve of (200) plane at FWHM can be measured by gamma-ray diffraction in vacuum with an Iridium 192 isotope with wavelength of 0.392 nanometer to be in the range of about 0.1 to 0.3 degree. The Gamma-ray cross section can be about 1 mm×10 mm.

This single crystal ceramic substrate can be placed in the molecular beam epitaxy machine for the application of a coating through an electron beam evaporation process. The substrate can be kept at about 1000° C., rotated at about 100 rpm, and coated with an iridium alloy including about 25 a/o % rhenium to a thickness of about 300 nm at a net coating rate of about 0.5 nm per second.

The electron beam evaporation of the iridium alloy can be carried out with two independent electron beam guns. Each gun can heat a single water cooled copper crucible containing either iridium or rhenium of 99.95 a/o % purity. The vacuum pressure before the start of evaporation can be about 5×10⁻⁹ torr.

After the coating operation is completed, the alloy-coated substrate can be removed from the chamber and put into a vacuum annealing furnace at about 1200° C. for about 5 hours at a vacuum of at least about 10⁻³ torr.

Subsequently, the alloy coated ceramic disc can be placed in a microwave plasma CVD reactor operating a power of at about 1.4 KW and about 2.45 Giga Hz. Diamond nucleation can be carried out at a sample stage biased voltage level of about negative 300 volts for one hour, with a methane/hydrogen gas concentration of 4%, a substrate temperature of 750° C., and a total vacuum pressure of 22 torrs. During this step, a nitrogen gas concentration of about 50 ppm can be maintained.

Subsequently, the growth conditions can be changed to a methane/hydrogen ratio of 1.5%, a microwave power of 5 KW, a vacuum pressure of 170 torrs, stage biased voltage of zero; a nitrogen concentration can be 50 ppm; an oxygen gas concentration at 0.1%; and a substrate temperature of about 1150° C.

After 24 hours, the single crystal diamond film having a depth of about 180 microns can be formed and the (200) lattice misorientation by rocking curve at FWHM can be measured to be about 0.2 degree. Afterwards, the methane/hydrogen ratio can be reduced to 1.0%; the oxygen concentration can be reduced to zero and the concentration of nitrogen gas can be increased to 500 ppm. After these conditions are maintained for about another 24 hours, the diamond lattice misorientation can be measured to be about 0.15 degrees.

### EXAMPLE 2

Ceramic can be prepared and utilized to grow a substantially single crystal cylinder having a diameter of 2 inches and a length of 10 inches using the Czochraiski crystal pulling process described in Example 1. The process includes adding a single seed crystal and the melt composition to the lower crystallization chamber. After the cylinder solidifies and is further processed to increase the uniformity of the crystal, portions of the cylinder having a substantially single crystal structure can be cut into disc shaped segments and the segments cleaned and polished. In a subsequent step, the disc's surface can be coated with an iridium alloy including about 10.0 a/o % nickel to provide a coating having a final thickness of about 500 nm. Finally, a large substantially single crystal diamond can be formed on the surface of the iridium-nickel coating using diamond growth conditions as described in Example 1.

### EXAMPLE 3

The general process illustrated in Example 1 can be repeated to grow a large diamond with the changes noted below. In this Example, a ceramic single crystal rod cylinder (rod) with a diameter of 3 inches and a length of 10 inches can be grown using the modified directional selection process. Sections of the crystalline rod can be cut into disc-shaped segments and polished. The polished segments, each comprising a substantially single crystal disc, can be used as substrates for the deposition of a coating of an iridium-rhenium-nickel alloy.

The alloy coating can be applied to the discs in a multiple hearth electron beam evaporation process. In this process, three hearths can be used with each hearth holding one metal selected from the group consisting of iridium, rhenium and nickel. The nickel can be 99.95 a/o % nickel and each of the remaining metals can be at least about 99.9 a/o % pure. The evaporation parameters can be controlled to form a coating about 500 nm thick comprising approximately 50.0 a/o % iridium, 30.0 a/o % rhenium and 20.0 a/o % nickel. During the evaporation process a vacuum can be maintained at about 10⁻⁹ torr or lower and the nickel substrate can be maintained at about 1350° C. while being rotated at about 60 rpm.

Finally, a large substantially single crystal diamond can be grown on the surface of the iridium alloy coated substrate using a microwave enhanced CVD process. This last step can be carried out substantially as described in Example 1 above except during BEN process, the vacuum pressure can be reduced to 20 torr and the microwave power can be raised to about 3 KW and during high growth rate process the microwave power can be increased to 8 KW.

All references, patents, patent applications and the like cited herein and not otherwise specifically incorporated by references in their entirety, are hereby incorporated by references in their entirety as if each were separately incorporated by reference in their entirety.

An abstract is included to aid in searching the contents of the application it is not intended to be read as explaining, summarizing or otherwise characterizing or limiting the invention in any way.

The present invention contemplates modifications as would occur to those skilled in the art. It is also contemplated that processes embodied in the present invention can be altered, duplicated, combined, or added to other processes as would occur to those skilled in the art without departing from the spirit of the present invention.

Further, any theory of operation, proof, or finding stated herein is meant to further enhance understanding of the present invention and is not intended to make the scope of the present invention dependent upon such theory, proof, or finding.

While the invention has been illustrated and described in detail in the figures, formulas and foregoing description, the same is considered to be illustrative and not restrictive in character, it is understood that only the preferred embodiments have been shown and described and that all changes and modifications that come within the spirit of the invention are desired to be protected.

### REFERENCES CITED U.S. PATENT DOCUMENTS

| | | |
|---|---|---|
| 1,793,672 | February 1931 | Bridgman |
| 3,260,505 | July 1966 | Versnyder |
| 3,494,709 | February 1970 | Piearcey |
| 3,536,121 | October 1970 | Piearcey |
| 3,519,063 | July 1970 | Piearcey |
| 3,532,155 | October 1970 | Kane et al. |
| 3,542,120 | November 1970 | Piearcey |
| 4,111,252 | September 1978 | Day et al |
| 4,190,094 | February 1980 | Giamei |
| 4,548,255 | October 1985 | Reiner et al |
| 4,534,821 | August 1985 | Sagaguchi et al |
| 4,997,636 | March 1991 | Prins |
| 5,298,286 | May 1994 | Yang et al |
| 5,387,310 | February 1995 | Shiomi et al. |
| 5,404,835 | April 1995 | Yoder |
| 5,449,531 | September 1995 | Zhu et al |
| 5,420,443 | May 1995 | Dreifus et al |
| 5,479,875 | January 1996 | Tachibana et al |
| 5,487,945 | January 1996 | Yang et al |
| 5,562,769 | October 1996 | Dreifus et al |
| 5,743,957 | April 1998 | Kobashi |
| 5,849,413 | December 1998 | Zhu et al |
| 5,863,324 | January 1999 | Kobashi et al |
| 6,080,378 | June 2000 | Yokoda et al |
| 6,096,129 | August 2000 | Saito et al |
| 6,110,541 | August 2000 | Lee et al |
| 6,383,288 | May 2002 | Hayashi et al |
| 6,899,761 | March 2005 | Eissler |
| 7,060,130 | June 2006 | Golding et al. |
| 7,128,794 | October 2006 | Veas |
| 2006/0203346 | September 2006 | Noguchi et al. |
| 2006/0266279 | November 2006 | Mokuno et al. |

### OTHER REFERENCES

1) Koji Kobashi, Diamond Films: Chemical Vapor Deposition for Oriented and Heteroepitaxial Growth, (London: Elsevier Science, 2005)
2) Jes Asmussen and D. K. Reinhard (Eds.), Diamond Films Handbook, (CRC Press, New York, 2002)
3) D. K. Bowen and B. K Tanner, High Resolution X-ray Diffractometry and Topography (Taylor & Francis, London, 1998)
4) Siredey et al, “Dendritic Growth and Crystalline Quality of Nickel Based Single Grains,” J. Crystal Growth 130, 132-146 (1933).

1. A method for growing a single crystal diamond comprising:
selecting a single crystal substrate including a single crystal ceramic platform having at least one flat surface and a coating fixed thereon, said coating including an iridium alloy containing iridium and a component selected from the group consisting of iron, cobalt, nickel, molybdenum, rhenium and a combination thereof;
providing a mixture of gases comprising methane and hydrogen; and
dissociating said methane in the presence of said substrate to cause deposition of a single diamond crystal onto said coating, said diamond crystal having a crystal structure corresponding to said crystal structure of said substrate.

2. A CVD diamond prepared according to the method of claim 1,
said diamond having a (200) diffraction peak and a full-width half maximum (FWHM) of said diffraction peak of less than five degrees, as determined by a method selected from the group consisting of an X-ray rocking curve method and a Gamma-ray rocking curve method.

3. A CVD diamond prepared according to the method of claim 1,
said diamond having a (200) diffraction peak and a full-width half maximum (FWHM) of said diffraction peak of less than one degree, as determined by a method selected from the group consisting of an X-ray rocking curve method rocking curve method and the Gamma-ray rocking curve method.

4. A CVD diamond prepared according to the method of claim 1,
said diamond having a (200) diffraction peak and a full-width half maximum (FWHM) of said diffraction peak of less than 0.2 degree, as determined by a method selected from the group consisting of an X-ray rocking curve method and a Gamma-ray rocking curve method.

5. The method according to claim 1,
wherein said iridium alloy comprises from about 99.99 a/o % to about 50 a/o % iridium.

6. The method according to claim 1,
wherein said oriented film includes alloy of iridium and molybdenum and a component selected from the group consisting of iron, cobalt, nickel, rhenium and a combination thereof, and
wherein said alloy comprises from about 99.99 a/o % to about 50 a/o % iridium and from about 0.01 a/o % to about 20.0 a/o % molybdenum.

7. The method according to claim 1,
wherein said oriented film includes an alloy of iridium and rhenium, and
wherein said rhenium comprises from about 0.01 a/o % to about 36 a/o %.

8. The method according to claim 7,
wherein said iridium alloy comprises from about 0.01 a/o % to about 30 a/o % rhenium.

9. The method according to claim 5,
wherein said iridium alloy comprises from about 0.01 a/o % to about 50 a/o % of said component.
